(19) United States
(12) Patent Application Publication
(10) Pub. No.: US 2012/0112333 A1
(43) Pub. Date: May 10, 2012

(54) SEMICONDUCTOR DEVICE WITH NESTED ROWS OF CONTACTS

(75) Inventors: Qiang Liu, Tianjin (CN); Qingchun He, Tianjin (CN); Zhaojun Tian, Tianjin (CN)

(73) Assignee: FREESCALE SEMICONDUCTOR, INC, Austin, TX (US)

(21) Appl. No.: 13/210,393

(22) Filed: Aug. 16, 2011

(30) Foreign Application Priority Data
Nov. 5, 2010 (CN) 201010539566.3

(51) Int. Cl. H01L 23/495; H01L 21/78; H01L 21/50

(52) U.S. Cl. 257/676; 438/123; 438/113; 174/529; 257/E23.031; 257/E21.499; 257/E21.599

(57) ABSTRACT

A molded surface mount semiconductor device has electrical contact elements disposed in a set of pairs of zigzag rows extending adjacent and generally parallel to opposite edges of an active face of a semiconductor die. Each of the pairs of rows includes an inner zigzag row of electrical contact elements nested inside an outer zigzag row of electrical contact elements. The electrical contact elements of the inner and outer zigzag rows are partially inter-digitated. A lead frame used in making the device also has a die pad located inside the set of pairs of zigzag rows, and an outer frame element located outside the set of pairs of zigzag rows, and which support the electrical contact elements of the inner and outer zigzag rows respectively.

### BACKGROUND OF THE INVENTION

The present invention is directed to semiconductor devices with nested rows of contacts and to a method of making such semiconductor devices.

Semiconductor devices, such as integrated circuits, comprise a semiconductor die (or chip) in a package with exposed electrical contact surfaces. The completed devices may be mounted on a support with electrical connections, such as a printed circuit board (‘PCB’). Using surface mount technology the electrical contact surfaces of the package can be soldered directly to corresponding pads on the support, providing mechanical attachment as well as electrical connections.

A completed surface mount device typically includes an electrically insulating molding material that encapsulates the semiconductor die so that the device presents a top face and a bottom, active face, which are generally rectangular or square, and transversely extending edges. The molding compound may encapsulate the semiconductor device completely, or may define an air cavity that is sealed with a ceramic or plastic lid. Typically, the device also has a pair of sets of electrical contact surfaces on opposite sides of the active face of the device (‘dual in-line package’) or two orthogonal pairs of sets of electrical leads on respective sides of the active face of the device (‘quad package’).

Typically, each set of electrical contact surfaces includes discrete elements (lead fingers) disposed side by side at intervals in rows at or adjacent a respective edge of the active face of the device for soldering to the electrical connections of the support. In order to increase the number of contact surfaces available, more than one row of electrical contact surfaces may be provided in each set on the respective side of the device. The adjacent rows at each respective side of the device are nested, extending parallel to each other and to the adjacent side of the device, an inner row being further from the adjacent side of the device than the outer row.

The semiconductor die may be mounted in the device on a pad or flag of the same material as the electrical contact surfaces, which is usually a metal, such as copper, which may be plated. The die pad may be exposed at the bottom face of the device, to assist cooling the die, known as an exposed-pad package. Alternatively, the die pad may be omitted, known as a non-exposed-pad package. In a non-exposed-pad package the die may be mounted directly on the discrete electrical contact elements. In each case, the die and electrical contact elements and any die pad are held together mechanically by the encapsulating molding material. The electrical contact elements of the device may be connected electrically to electrical contact pads on the die with bond wires, of gold, copper or aluminum for example, accommodating differential thermal expansion of the die and the package materials.

A prevalent technique used in manufacturing such a surface mount device includes forming an array of lead frames in a strip or sheet of electrically conductive material, usually metal, by etching and/or stamping. Each lead frame has tie bars forming frame elements common to adjacent lead frames. The tie bars support in the array the sets of discrete electrical contact portions, which will form the sets of electrical contacts of the completed device after singulation, and any die pad for mounting the die. The array of lead frames may be a single strip but typically comprises a two-dimensional array, with the supporting frame structure of the complete array comprising surrounding tie bars on the outer edges of the array and intersecting intermediate tie bars common to adjacent lead frames.

In a typical surface mount semiconductor device packaging process using lead frames, the semiconductor dies are mounted on and connected electrically to respective ones of the lead frames. The encapsulation material is then molded over and around the lead frame strip or sheet, possibly with a lid in the case of an air cavity package, so as to encapsulate the integrated circuit dies, the electrical contact surface elements and the bonded connection wires of each of the lead frames. The individual devices are then separated by a singulation process, in which the lead frame strip or sheet is cut apart. The singulation may be a saw operation or a punch operation. If desired, saw singulation enables the molding compound to be applied over the entire array, being cut subsequently during the singulation process. During saw singulation, a saw blade is advanced along ‘saw streets’ that extend between the electrical contact surface elements of adjacent lead frames, so as to cut off the supporting frame structures of the lead frames from the electrical contact surface portions of the lead frames and separate the individual devices from each other. During punch singulation, after the molding compound is applied to the individual devices, the punch tool is used to singulate the devices along lines between the adjacent devices.

Minimum values are specified for the size of the individual electrical contact surfaces in the bottom active face of the device and for the spacing between adjacent electrical contact surfaces (pitch). Such specifications necessitate a compromise between the overall size of the bottom active face of the device and the number of individual electrical contact surfaces. It is desirable to reduce package sizes while maintaining or increasing the number of individual electrical contact surfaces, especially since continuing miniaturization of the semiconductor dies makes it possible to increase the complexity of the electronic systems they contain, which tends to increase the number of inputs and outputs for a given die size.

### BRIEF DESCRIPTION OF THE DRAWINGS

The present invention is illustrated by way of example and is not limited by embodiments thereof shown in the accompanying figures, in which like references indicate similar elements. Elements in the figures are illustrated for simplicity and clarity and have not necessarily been drawn to scale.

FIG. 1 is a top view of a lead frame at a stage before molding in a known method of making semiconductor devices;

FIG. 2 is a top view of a lead frame at a stage before molding in a method of making semiconductor devices in accordance with one embodiment of the invention;

FIG. 3 is a detail view of an example of the lead frame of FIG. 2 in accordance with one embodiment of the invention;

FIG. 4 is a sectional view of the lead frame from the line 4-4 of FIG. 2 after taping, mounting a semiconductor die and wire bonding;

FIG. 5 is a sectional view similar to FIG. 4 of an example of a semiconductor device in accordance with an embodiment of the invention after molding, de-taping and singulation;

FIG. 6 is a bottom view of the semiconductor device of FIG. 5; and

FIG. 7 is a flow chart illustrating a method of assembling the semiconductor devices illustrated in FIGS. 2 to 6.

### DETAILED DESCRIPTION OF PREFERRED EMBODIMENTS

In one embodiment, the present invention is directed to a semiconductor device, including a semiconductor die, electrical contact elements individually connected with the semiconductor die, and a molding material that covers or encapsulates the semiconductor die and electrical contact elements such that the device presents a top face, a bottom active face in which said electrical contact elements are exposed, and transversely extending edges. The electrical contact elements are disposed in a set of pairs of zig-zag rows extending at or adjacent and generally parallel to opposite edges of said active face, each of said pairs comprising an inner zigzag row of electrical contact elements nested inside an outer zigzag row of electrical contact elements, said electrical contact elements of said inner zigzag row and said outer zigzag row being partially inter-digitated.

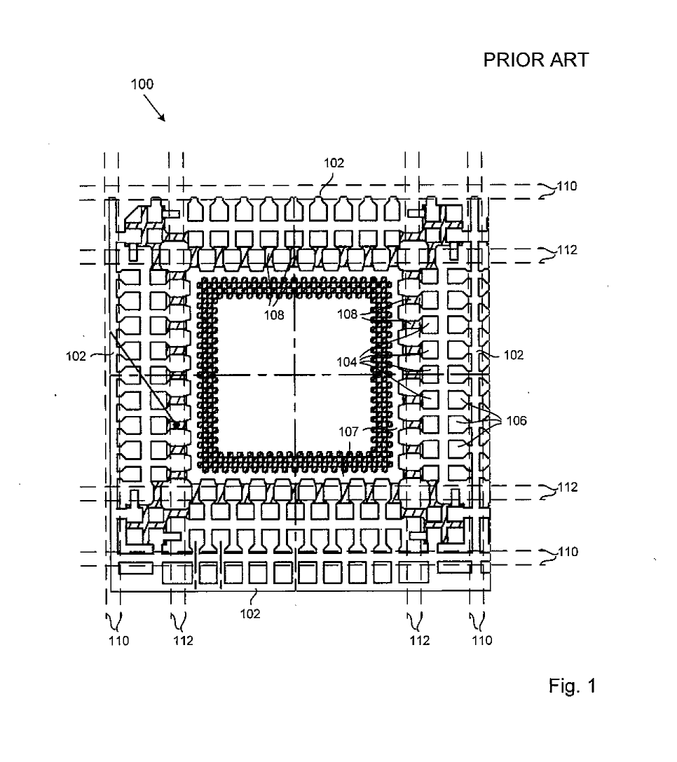

Referring now to FIG. 1, a single lead frame 100 in a two-dimensional array of lead frames used in a known method of making quad package semiconductor devices is shown. The lead frame 100 comprises a rectangular (in this case square) frame structure 102 surrounding the lead frame 100. Adjacent to each side of the device, the lead frame 100 includes a first, straight row of electrical contact elements 104 and a second, straight row of electrical contact elements 106. The first row of electrical contact elements 104 is an inner row, positioned further from the adjacent side of the device than the second row, which is an outer row. The electrical contact elements 104 of the first, inner row are disposed facing and directly aligned with the electrical contact elements 106 of the second, outer row.

The electrical contact elements 104 of the first, inner row are initially supported by an inner frame element 107, which may be part of a die pad, by the intermediary of connection bars 108. The electrical contact elements 106 of the second, outer row are directly supported by an outer frame element 102. The connection bars 108 and the frame elements 102 and 107 connect with, and support the electrical contact elements 104 and 106 mechanically but also connect them electrically as well. These electrical connections of the electrical contact elements 104 and 106 must be cut once the electrical contact elements 104 and 106 are supported by further structure of the device, notably molding compound. The frame element 102 may be cut during normal saw or punch singulation of the devices, after molding and de-taping, by sawing or punching along streets 110 and the molding compound in the streets is cut at the same time. However, when cutting the connection bars 108 along streets 112, a saw cuts from the bottom active face of the device only through the metal of the lead frame and penetrates as little as possible the molding compound. Alternatively, the metal of the lead frame may be cut by etching the connection bars 108 along the streets 112, without etching the molding compound.

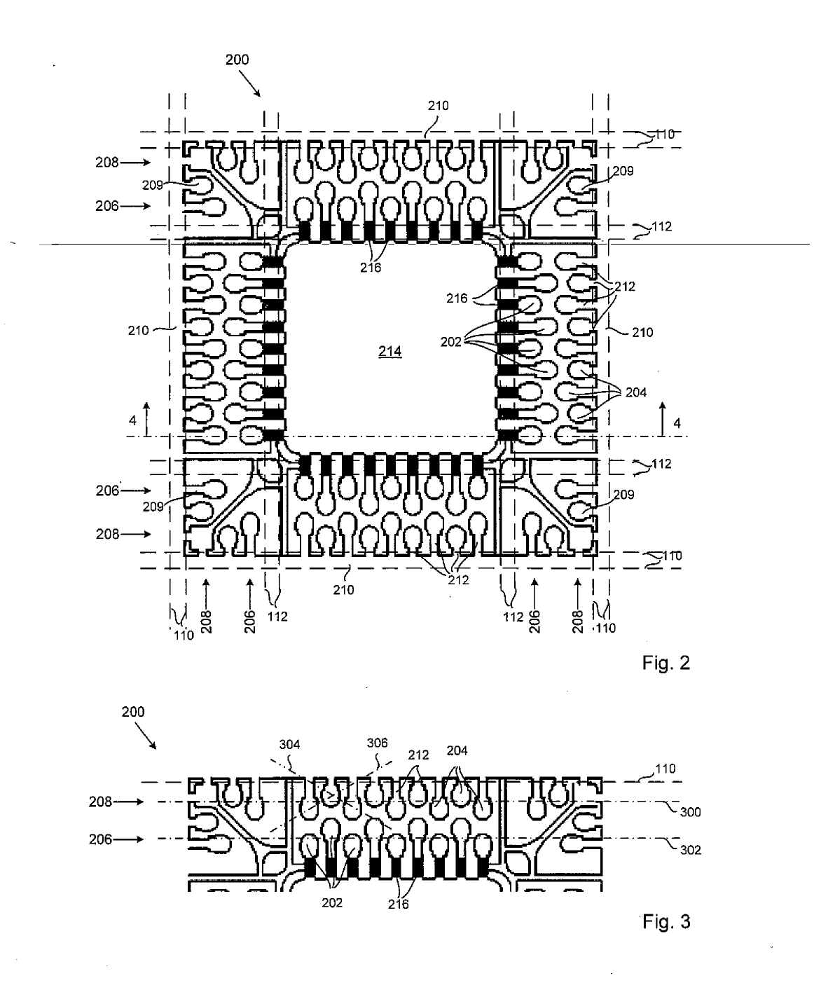

FIGS. 2 to 7 illustrate a method of making semiconductor devices, a lead frame 200 used in such a method, and a semiconductor device 500, shown in FIGS. 5 and 6, in accordance with an example of an embodiment of the present invention.

In this example, the lead frame array is used in producing semiconductor devices 500 which each present respectively a top face 504, a bottom active face 506, and transversely extending edges 508. Each lead frame 200 of the array comprises electrical contact elements 202 and 204 disposed in a set of pairs of zigzag rows extending at or adjacent and generally parallel to opposite edges 508 of the active face, each pair comprising an inner zigzag row 206 of electrical contact elements 202 nested inside an outer zigzag row 208 of electrical contact elements 204, the electrical contact elements 202 and 204 of the inner zigzag row and the outer zigzag row being partially inter-digitated. Each lead frame 200 also comprises an inner frame element 214, which may be a die pad, disposed inside the set of pairs of zigzag rows, and an outer frame element 210 disposed outside the set of pairs of zigzag rows. The inner and outer frame elements 214 and 210 connect with and support the electrical contact elements 202 and 204 of the inner and outer zigzag rows 206 and 208 respectively. The outer frame element 208 of adjacent lead frames 200 of the array is common to the adjacent lead frames.

In this example, the semiconductor device 500 comprises a semiconductor die 402, electrical contact elements 202 and 204 individually connected electrically with the semiconductor die 402, and an electrically insulating molding material 502 which encapsulates the semiconductor die and the electrical contact elements. The device 500 presents a top face 504, a bottom active face 506 in which the electrical contact elements 202 and 204 are exposed, and transversely extending edges 508. The electrical contact elements 202 and 204 are disposed in a set of pairs of zigzag rows extending at or adjacent and generally parallel to opposite edges 508 of the active face 504, each of the pairs comprising an inner zigzag row 206 of electrical contact elements nested inside an outer zigzag row 208 of electrical contact elements, the electrical contact elements of the inner zigzag row 206 and the outer zigzag row 208 being partially inter-digitated.

FIGS. 2 to 7 illustrate a method of assembling a quad package device having pairs of zigzag rows 206 and 208 of electrical contact elements 202 and 204 at each of the four sides of the device. It will be appreciated that the method can be adapted to producing an in-line package with first and second pairs of zigzag rows of electrical contact elements at only two opposite sides of the device. FIGS. 2 to 7 illustrate a method of assembling an exposed die pad semiconductor device 500. It will be appreciated that the method can be adapted to producing a non-exposed die pad semiconductor device.

In more detail, FIGS. 2 to 4 show an example of a single lead frame 200 of a two-dimensional array of similar lead frames formed by stamping and/or etching, for example. Each of the lead frames 200 comprises two orthogonal sets of the pairs of zigzag rows 206 and 208, the pairs of zigzag rows being disposed adjacent respective sides of the lead frame, and the semiconductor device 500 (see FIGS. 5 and 6) forming a quad package. As shown in the detail view of FIG. 3, the inner zigzag rows 206 of electrical contact elements extend adjacent and generally parallel to an edge 508 of the active face 504, as shown by the chain dotted median line 300. Similarly, the outer zigzag rows 208 of electrical contact elements extend at or adjacent and generally parallel to an edge 508 of the active face 504, as shown by the chain dotted median line 302.

The individual electrical contact elements 202 and 204 are offset or staggered alternately on opposite sides of the median line 300 or 302 of the respective inner or outer row 206 or 208. The lines joining the centers of adjacent contact elements of a same zigzag row 206 or 208 make an offset angle with the length of the row, as shown by the double chain dotted lines 304 and 306. The offset angle is chosen to achieve a compromise between the reduced pitch of the electrical contact elements 202 and 204 in the x-direction, parallel to the adjacent edge 508 of the active face 506, and a corresponding increase in the size of the package in the y-direction perpendicular to the adjacent edge 508 of the active face 506. The reduced pitch is obtained without reducing the spacing between contact elements of the same row nor between contact elements of different rows. The offset angle in this example is approximately 30°. In other examples, the offset angle is between 20° and 45°.

The offset is sufficient for the reduced pitch in the x-direction to enable an increased number of the electrical contact elements 202 or 204 on each side of the lead frame 200 compared to the configuration of FIG. 1. However, the offset is sufficiently small that the y-dimensions of the adjacent offset electrical contact elements 202 or 204 of the same row 206 or 208 overlap partially. The inner zigzag row 206 of electrical contact elements is nested inside the outer zigzag row 208 of electrical contact elements, and the electrical contact elements of the inner zigzag row 206 and the outer zigzag row 208 are partially inter-digitated, so that the y-direction size increase is limited. Since the electrical contact elements of the inner zigzag row 206 and the outer zigzag row 208 are partially inter-digitated, the y-dimensions of the electrical contact elements 202 of the inner row 206 which are closer to the edge 508 of the device overlap partially the y-dimensions of the electrical contact elements 204 of the outer row 208 which are further from the edge 508 of the device.

In one example, a package of the kind shown in FIG. 1 of size 7 mm by 7 mm has 76 electrical contact elements 202 and 204. A package of the kind shown in FIG. 2 with an offset angle of 30°, has 92 electrical contact elements 202 and 204, an increase of approximately 20%, for a much smaller increase in the package size. In this example, with an offset angle of 30°, the distance between centers of adjacent contact elements of the same zigzag row 206 or 208 is 0.44 mm and the reduced pitch in the x-direction is 0.38 mm. In this example, the offset of the contact elements of the same zigzag row 206 or 208 adds twice 0.22 mm on the package size, which represents approximately 6% per side compared to the size 7 mm by 7 mm of the package of the kind shown in FIG. 1, and adds 13% on the package area, compared to 20% more pads.

In this example of an embodiment of the invention, the set of pairs of zigzag rows of electrical contact elements in each lead frame has four corner areas 209. Each corner area includes electrical contact elements 204 only of the outer zigzag rows 208 and no electrical contact elements 202 of the inner zigzag rows 206. The offset geometry of the outer zigzag rows enables four electrical contact elements 204 to be disposed in each corner area 209, two closer to the edges 508 of the active face 506 of the device and two further away.

As seen in FIGS. 2 and 3, in the lead frame 200 before molding, the contact elements 204 of the outer zigzag rows 208 are supported by a generally rectangular outer frame element 210 which surrounds the lead frame 200. The members of the outer frame element 210 are common to adjacent lead frames of the array of lead frames. The contact elements 204 of the outer zigzag rows 208 are of rounded shape and are connected mechanically to the frame element 210 by links 212. The links 212 extend across singulation streets 110, so as to be severed and separate the contact elements 204 from the frame element 210 on singulation of the devices 500. The longer links 212, which connect to those of the contact elements 204 which are further from the frame element 210 are narrower than the width of the contact elements 204, so as to maintain a minimum x-direction spacing between the links 212 and those of the contact elements 204 which are closer to the frame element 210.

In this example, each of the lead frames 200 comprises a respective die pad 214, disposed centrally between the inner zigzag rows 206 of electrical contact elements 202 and serving also as an inner frame element supporting the electrical contact elements 202. The contact elements 202 of the inner zigzag rows 206 are of similar rounded shape to the contact elements 204 and are connected mechanically to the die pad 214 by links 216. The links 216 extend across streets 112, shown shaded, so as to be severed and separate the contact elements 202 from the die pad after molding. In another example, where the device is a non-exposed pad device, the inner zigzag rows 206 of electrical contact elements 202 are supported before molding by an inner frame element (not shown) of similar shape to, but smaller than, the frame element 210. The inner frame element is again connected to the inner zigzag rows 206 of electrical contact elements 202 by links 216 in the lead frame before molding, the links extending across the streets 112. In each case, the longer links 216, which connect to those of the contact elements 202 which are further from the die pad 214 or inner frame element are narrower than the width of the contact elements 202, so as to maintain a minimum spacing in the x-direction between the links 216 and those of the contact elements 202 which are closer to the die pad 214 or inner frame element.

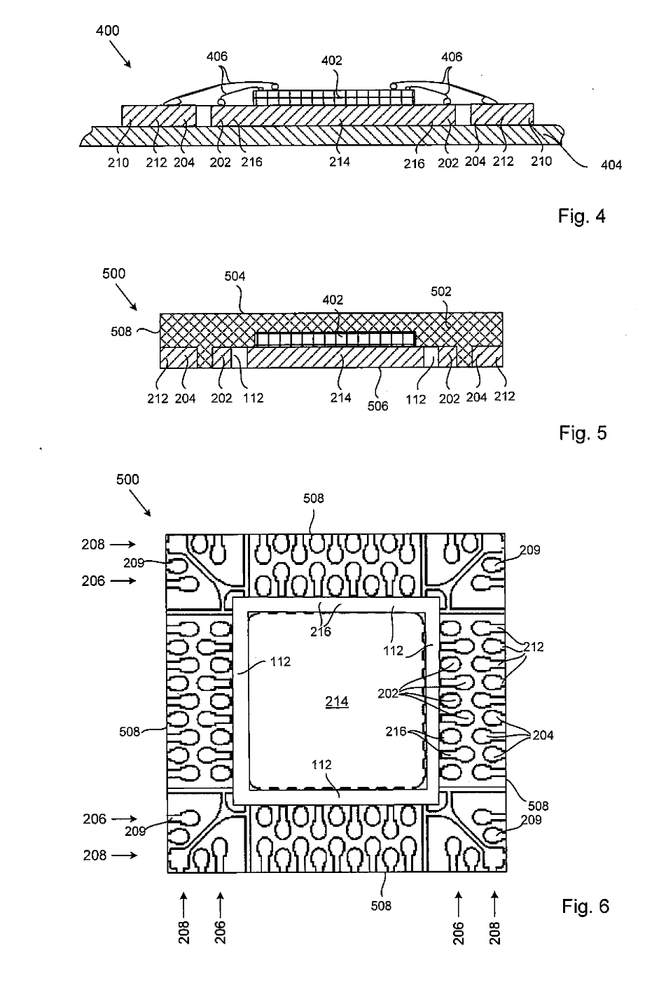

Examples of further stages in the production of semiconductor devices 500 in accordance with an embodiment of the present invention are shown in FIGS. 4, 5 and 6. As shown in FIG. 4, an assembly 400 is produced by mounting the array of lead frames 200 on a sheet of adhesive tape 404 and mounting the semiconductor dies 402 on the lead frames 200. Alternatively, the semiconductor dies 402 can be mounted on the lead frames 200 before the array of lead frames is mounted on the sheet of adhesive tape 404.

In this example, the electrical contact elements 202 and 204 of each lead frame 200 present top surfaces to which wires 406, of gold, copper or aluminum for example, are bonded. The wires 406 connect the electrical contact elements individually to contacts on the semiconductor die 402, to which the wires are bonded also. The bottom surfaces of the electrical contact elements 202 and 204 will be left exposed in the bottom active face of the finished device around the periphery of the semiconductor die 402, for connection to external devices.

In the next step, the assemblies 400 are encapsulated using a molding compound 502 on the sheet of adhesive tape 404. If the devices are to be singulated by sawing, the molding compound 502 may be applied uniformly over the array of lead frames 200 and assemblies 400. If the devices are to be singulated by punching, the molding compound 502 may be applied individually over the lead frames 200 and assemblies 400.

The sheet of adhesive tape 404 is then removed. The inner zigzag rows 206 of electrical contact elements 202 are separated from the die pad 214 or inner frame element by cutting partially through the thickness of the array of lead frames 200 along the column and row streets 112, by sawing or masked etching for example, so as to cut the links 216. The encapsulated assemblies 400 are then singulated by sawing or punching along the column and row streets 110 to produce the semiconductor devices 500. The links 212 are cut by the singulation process so as to separate the outer rows 208 of electrical contact elements 204 from the outer frame element 210, which is removed. The molding compound 502 leaves the inner and outer zigzag rows 206 and 208 of electrical contact elements 202 and 204 exposed adjacent sides 508 of the active face 506 of the respective semiconductor device 500.

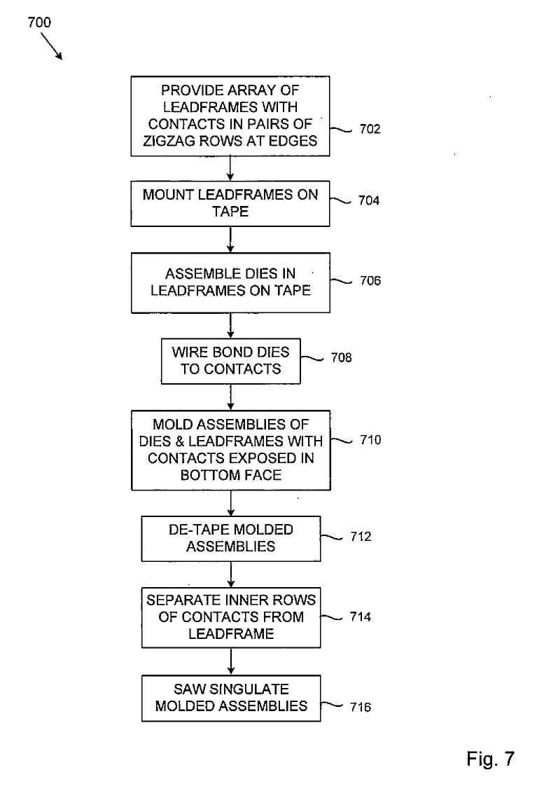

FIG. 7 is a summary of a method 700 of making a semiconductor device, as described above with reference to FIGS. 2 to 6. The method comprises providing a semiconductor die 402, providing electrical contact elements 202 and 204, connecting the electrical contact elements electrically with the semiconductor die. An electrically insulating molding material 502 is applied, which encapsulates the semiconductor die and the electrical contact elements so that the device presents a top face 504, a bottom active face 506 in which the electrical contact elements are exposed, and transversely extending edges 508. The electrical contact elements are disposed in a set of pairs 206 and 208 of zigzag rows extending at or adjacent and generally parallel to opposite edges 508 of the active face 506. Each of the pairs comprises an inner zigzag row 206 of electrical contact elements 202 nested inside an outer zigzag row 208 of electrical contact elements 204, the electrical contact elements of the inner zigzag row 206 and the outer zigzag row 208 being partially inter-digitated.

In more detail, the method 700 starts at 702 by producing an array of lead frames 200 having electrical contact elements 202 and 204 in sets of pairs of zigzag rows 206 and 208 at or adjacent opposite edges 508 of the active face 506. At 704, the array of lead frames 200 is mounted on a sheet of adhesive tape 404. Assemblies 400 are produced at 706 by mounting semiconductor dies 402 on each of the lead frames 200.

At 708, the semiconductor dies 402 are connected electrically to the electrical contact elements 202 and 204 by wire bonding. The assemblies 400 are then encapsulated at 710 using a molding compound 502. At 712, the adhesive tape 404 is removed from the encapsulated assemblies 400. The inner zigzag rows 206 of electrical contact elements 202 are separated from the die pad 214 or inner frame element at 714 by cutting partially through the thickness of the array along the column and row streets 112, by sawing or masked etching for example, so as to cut the links 216. The assemblies 400 are then saw singulated at 716 to produce the semiconductor devices 500.

In the foregoing specification, the invention has been described with reference to specific examples of embodiments of the invention. It will, however, be evident that various modifications and changes may be made therein without departing from the broader spirit and scope of the invention as set forth in the appended claims.

For example, the semiconductor device described herein can comprise any semiconductor material or combinations of materials, such as gallium arsenide, silicon germanium, silicon-on-insulator (SOI), silicon, monocrystalline silicon, the like, and combinations of the above.

The terms “front,” “back,” “top,” “bottom,” “over,” “under” and the like in the description and in the claims, if any, are used for descriptive purposes and not necessarily for describing permanent relative positions. It is understood that the terms so used are interchangeable under appropriate circumstances such that the embodiments of the invention described herein are, for example, capable of operation in other orientations than those illustrated or otherwise described herein.

Any arrangement of components to achieve the same functionality is effectively “associated” such that the desired functionality is achieved. Hence, any two components herein combined to achieve a particular functionality can be seen as “associated with” each other such that the desired functionality is achieved, irrespective of architectures or intermedial components. Likewise, any two components so associated can also be viewed as being “operably connected,” or “operably coupled,” to each other to achieve the desired functionality.

Furthermore, those skilled in the art will recognize that boundaries between the above described operations merely illustrative. The multiple operations may be combined into a single operation, a single operation may be distributed in additional operations and operations may be executed at least partially overlapping in time. Moreover, alternative embodiments may include multiple instances of a particular operation, and the order of operations may be altered in various other embodiments.

Also for example, in one embodiment, the illustrated examples may be implemented as circuitry located on a single integrated circuit within a single complete package of the semiconductor device. Alternatively, the examples may be implemented as more than one separate integrated circuits or separate devices interconnected with each other in a suitable manner within a single complete package of the semiconductor device. However, other modifications, variations and alternatives are also possible. The specifications and drawings are, accordingly, to be regarded in an illustrative rather than in a restrictive sense.

In the claims, the word ‘comprising’ does not exclude the presence of other elements or steps then those listed in a claim. The terms “a” or “an,” as used herein, are defined as one or more than one. Also, the use of introductory phrases such as “at least one” and “one or more” in the claims should not be construed to imply that the introduction of another claim element by the indefinite articles “a” or “an” limits any particular claim containing such introduced claim element to inventions containing only one such element, even when the same claim includes the introductory phrases “one or more” or “at least one” and indefinite articles such as “a” or “an.” The same holds true for the use of definite articles. Unless stated otherwise, terms such as “first” and “second” are used to arbitrarily distinguish between the elements such terms describe. Thus, these terms are not necessarily intended to indicate temporal or other prioritization of such elements The mere fact that certain measures are recited in mutually different claims does not indicate that a combination of these measures cannot be used to advantage.

1. A semiconductor device, comprising:
a semiconductor die;
electrical contact elements individually connected with said semiconductor die; and
an electrically insulating molding material that encapsulates said semiconductor die and said electrical contact elements so that the device presents a top face, a bottom active face in which said electrical contact elements are exposed, and transversely extending edges;
wherein said electrical contact elements are disposed in a set of pairs of zigzag rows extending at or adjacent and generally parallel to opposite edges of said active face, each of said pairs comprising an inner zigzag row of electrical contact elements nested inside an outer zigzag row of electrical contact elements, said electrical contact elements of said inner zigzag row and said outer zigzag row being partially inter-digitated.

2. The semiconductor device of claim 1, wherein said semiconductor die is mounted on a die pad disposed between said set of pairs of zigzag rows of electrical contact elements.

3. The semiconductor device of claim 2, wherein said molding material leaves said die pad exposed in said active face of the semiconductor device.

4. The semiconductor device of claim 1, wherein said electrical contact elements are disposed in two orthogonal sets of said pairs of zigzag rows, said semiconductor device forming a quad package.

5. The semiconductor device of claim 1, wherein said set of pairs of zigzag rows of electrical contact elements has four corner areas, and wherein each corner area includes electrical contact elements only of said outer zigzag row.

6. A lead frame array for semiconductor devices that each present respectively a top face, a bottom active face, and transversely extending edges, each lead frame of said array comprising:
electrical contact elements disposed in a set of pairs of zigzag rows extending at or adjacent and generally parallel to opposite edges of said active face, each pair comprising an inner zigzag row of electrical contact elements nested inside an outer zigzag row of electrical contact elements, said electrical contact elements of said inner zigzag row and said outer zigzag row being partially inter-digitated; and
an inner frame element disposed inside said set of pairs of zigzag rows, and an outer frame element disposed outside said set of pairs of zigzag rows, said inner and outer frame elements connecting with and supporting said electrical contact elements of said inner and outer zigzag rows respectively, and said outer frame element of adjacent lead frames of said array being common to said adjacent lead frames.

7. The lead frame array of claim 6, wherein said inner frame element comprises a die pad disposed between said set of pairs of zigzag rows of electrical contact elements for mounting said semiconductor die.

8. The lead frame array of claim 6, wherein said electrical contact elements are disposed in two orthogonal sets of said pairs of zigzag rows, whereby to form a quad package for said semiconductor device.

9. The lead frame array of claim 6, wherein each lead frame has four corner areas, and wherein each corner area includes electrical contact elements only of said outer zigzag row.

10. A method of making a semiconductor device, comprising:
providing a semiconductor die;
providing electrical contact elements;
connecting said electrical contact elements electrically with said semiconductor die; and
encapsulating with a molding material said semiconductor die and said electrical contact elements so that the device presents a top face, a bottom active face in which said electrical contact elements are exposed, and transversely extending edges;
wherein said electrical contact elements are disposed in a set of pairs of zigzag rows extending at or adjacent and generally parallel to opposite edges of said active face, each of said pairs comprising an inner zigzag row of electrical contact elements nested inside an outer zigzag row of electrical contact elements, said electrical contact elements of said inner zigzag row and said outer zigzag row being partially inter-digitated.

11. The method of making a semiconductor device of claim 10, further comprising:
providing a lead frame comprising said electrical contact elements, an inner frame element disposed inside said set of pairs of zigzag rows, and an outer frame element disposed outside said set of pairs of zigzag rows, said inner and outer frame elements connecting with and supporting said electrical contact elements of said inner and outer zigzag rows respectively; and
separating said electrical contact elements of said inner and outer zigzag rows from said inner and outer frame elements.

12. The method of making a semiconductor device of claim 11, wherein said lead frame is provided as part of an array of lead frames comprising respective sets of pairs of said inner and outer zigzag rows of electrical contact elements, and respective inner frame elements disposed inside said set of pairs of zigzag rows, and outer frame elements disposed outside said set of pairs of zigzag rows, said outer frame elements being common to adjacent lead frames of said array; and separating said electrical contact elements of said inner and outer zigzag rows from said inner and outer frame elements includes singulating said plurality of semiconductor devices.

13. The method of making a semiconductor device of claim 12, wherein separating said electrical contact elements of said inner zigzag rows from said inner frame elements includes cutting connections between said inner frame elements of said lead frame and said electrical contact elements of said inner zigzag rows after applying said molding material.

14. The method of making a semiconductor device of claim 10, wherein said electrical contact elements are disposed in two orthogonal sets of said pairs of zigzag rows, said semiconductor device forming a quad package.
